(19) United States
(12) Patent Application Publication
(10) Pub. No.: US 2020/0304124 A1
(43) Pub. Date: Sep. 24, 2020

(54) METHODS AND APPARATUS FOR A CAPACITIVE SENSOR

(71) Applicant: SEMICONDUCTOR COMPONENTS INDUSTRIES, LLC, Phoenix, AZ (US)

(72) Inventor: Yasunori YAMAMOTO, Ora-gun (JP)

(73) Assignee: SEMICONDUCTOR COMPONENTS INDUSTRIES, LLC, Phoenix, AZ (US)

(21) Appl. No.: 16/455,161

(22) Filed: Jun. 27, 2019

Related U.S. Application Data
(60) Provisional application No. 62/822,190, filed on Mar. 22, 2019.

(51) Int. Cl. H03K 17/955; G01D 5/24

(52) U.S. Cl. CPC H03K 17/955; G01D 5/24

(57) ABSTRACT

Various embodiments of the present technology may provide methods and apparatus for a capacitive sensor. The capacitive sensor may include two sensor pads that have overlapping electric fields and operate independent from each other. The capacitive sensor may also include a ground electrode positioned adjacent to the sensor pads.

This application claims the benefit of U.S. Provisional Patent Application No. 62/822,190, filed on Mar. 22, 2019, the entire contents of which is incorporated herein by reference.

### BACKGROUND OF THE TECHNOLOGY

Capacitive sensors operate by detecting changes in the capacitance formed between two electrodes, commonly referred to as a transmission electrode and a sense electrode. A sensing circuit can recognize an object based on changes in the capacitance and may be configured to determine the location, pressure, direction, speed, and acceleration of the object as it is approaches and/or contacts the capacitive sensor.

Various applications for the capacitive sensor may involve “hands-free” operation of a device. In such a case, the capacitive sensor operates as a proximity sensor to detect objects within the electric field of the sensor and use the changes in the electric field to perform an automatic operation of the device. For example, a vehicle may utilize a capacitive sensor to provide “hands-free” operation of a trunk lid that opens when a person makes a kicking motion near the rear bumper of the vehicle where the sensor is located. However, conventional sensors used in “hands-free” applications are known to malfunction and/or activate under non-kick (non-ideal) conditions, such as when the person is merely standing next to the vehicle or when a small animal passes near the sensor.

### SUMMARY OF THE INVENTION

Various embodiments of the present technology may provide methods and apparatus for a capacitive sensor. The capacitive sensor may include two sensor pads that have overlapping electric fields and operate independent from each other. The capacitive sensor may also include a ground electrode positioned adjacent to the sensor pads.

### BRIEF DESCRIPTION OF THE DRAWINGS

A more complete understanding of the present technology may be derived by referring to the detailed description when considered in connection with the following illustrative figures. In the following figures, like reference numbers refer to similar elements and steps throughout the figures.

FIG. 1 representatively illustrates an application of a proximity sensor system in accordance with an exemplary embodiment of the present technology;

FIG. 2 is a block diagram of the proximity sensor system in accordance with an exemplary embodiment of the present technology;

FIG. 3 representatively illustrates a cross-sectional view of a capacitive sensor in accordance with a first embodiment of the present technology;

FIG. 4 representatively illustrates a front view of the capacitive sensor of FIG. 3;

FIG. 5 representatively illustrates a back view of the capacitive sensor of FIG. 3;

FIG. 6 representatively illustrates a cross-section view of a capacitive sensor in accordance with a second embodiment of the present technology;

FIG. 7 representatively illustrates a front view of the capacitive sensor of FIG. 6;

FIGS. 8A-8J representatively illustrate cross-sectional views of a capacitive sensor in accordance with various embodiments of the present technology;

FIG. 9 is a timing diagram for operating the proximity sensor system in accordance with a first operation of the present technology;

FIG. 10 is a timing diagram for operating the proximity sensor system in accordance with a second operation of the present technology;

FIG. 11 representatively illustrates a capacitive sensor during a first condition and in accordance with an exemplary embodiment of the present technology;

FIG. 12A is a graph of sensitivity waveforms of the capacitive sensor of FIG. 11 and in accordance with the present technology;

FIG. 12B is a graph of sensitivity waveforms of a conventional capacitive sensor during the first condition;

FIG. 13 representatively illustrates a capacitive sensor during a second condition and in accordance with an exemplary embodiment of the present technology;

FIG. 14A is a graph of sensitivity waveforms of the capacitive sensor of FIG. 13 and in accordance with the present technology;

FIG. 14B is a graph of sensitivity waveforms of a conventional capacitive sensor during the second condition;

FIG. 15 representatively illustrates a capacitive sensor during a third condition and in accordance with an exemplary embodiment of the present technology;

FIG. 16A is a graph of sensitivity waveforms of the capacitive sensor of FIG. 15 and in accordance with the present technology;

FIG. 16B is a graph of sensitivity waveforms of a conventional capacitive sensor during the third condition;

FIG. 17 representatively illustrates a capacitive sensor during a fourth condition and in accordance with an exemplary embodiment of the present technology;

FIG. 18A is a graph of sensitivity waveforms of the capacitive sensor of FIG. 17 and in accordance with the present technology;

FIG. 18B is a graph of sensitivity waveforms of a conventional capacitive sensor during the fourth condition; and

FIG. 19 representatively illustrates a sensor pad in accordance with an exemplary embodiment of the present technology.

### DETAILED DESCRIPTION OF EXEMPLARY EMBODIMENTS

The present technology may be described in terms of functional block components and circuit diagrams. Such functional blocks and circuit diagrams may be realized by any number of components configured to perform the specified functions and achieve the various results. For example, the present technology may employ various types of sensing circuitry, amplifiers, signal converters, microcontrollers, logic circuits, power sources, and the like, which may carry out a variety of functions. The methods and apparatus for a capacitive sensor according to various aspects of the present technology may operate in conjunction with any suitable device and/or system where a “hand-free” function is desired, such as a vehicle system having a “hands-free” operating trunk and/or door, an automatic door system, and automated medical equipment, and the like.

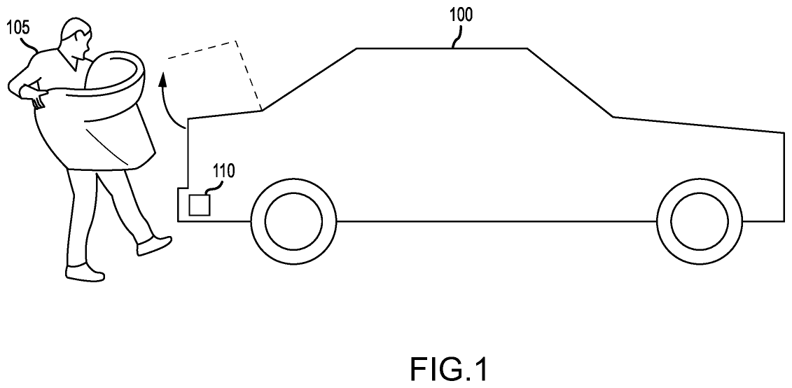

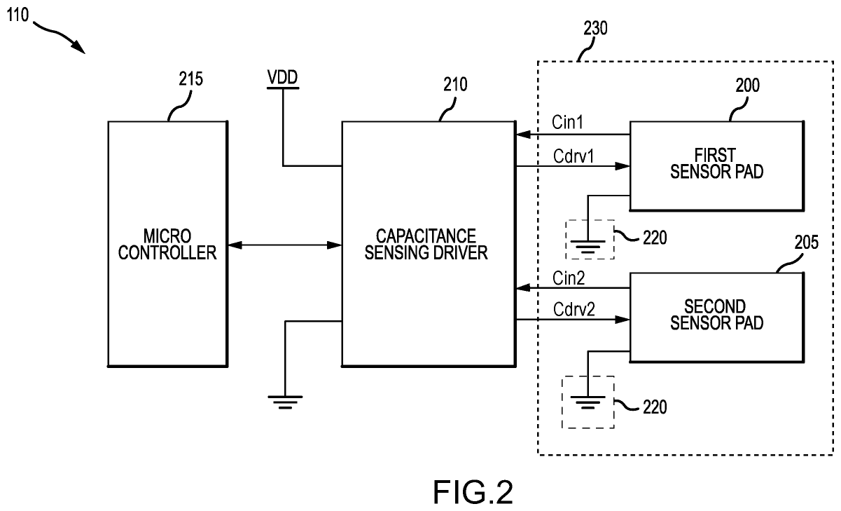

Referring to FIGS. 1 and 2, in various embodiments of the present technology, a sensor system 110 may be configured to sense or otherwise detect an object near the sensor system 110. In addition, the sensor system 110 may be configured to generate various control signals to indicate the presence of the object. In other words, the sensor system 110 may be configured as a proximity sensor system.

In one application, the sensor system 110 may be used to provide a “hands-free” operation of a device, such as a trunk lid on a vehicle 100. In the present application, the sensor system 110 may be affixed, either permanently or temporarily, to a rear bumper of the vehicle 100, such that when a person 105 gestures (for example, in a kicking motion) near the sensor system 110, the trunk lid will open automatically.

In various embodiments, the sensor system 110 may comprise a capacitive sensor 230, a capacitance sensing driver circuit 210, and a microcontroller 215 that operate together to measure changes in the capacitive sensor 230, perform signal processing, determine whether the changes in the capacitive sensor 230 give rise to an actionable event, and generate a control signal to indicate the actionable event. The capacitive sensor 230 may comprise various electrodes positioned in a particular manner to detect a particular gesture. For example, one or more electrodes may be positioned to detect two points on a foot, such as an ankle and a toe, during a kicking motion.

In an exemplary embodiment, the capacitive sensor 230 may be configured to generate an electric field that can be measured according to changes in a capacitance of the capacitive sensor 230. For example, the capacitive sensor 230 may comprise a first sensor pad 200 and a second sensor pad 205 positioned adjacent to each other and operate independent from each other. In various embodiments, the first sensor pad 200 may be configured to generate a first electric field 305 and a corresponding first input signal Cin1 that represents a capacitance of the first sensor pad 200. Similarly, the second sensor pad 205 may be configured to generate a second electric field 310 and a corresponding second input signal Cin2 that represents a capacitance of the second sensor pad 205. In addition, the first and second pads 200, 205 may be positioned adjacent to each other, such that a portion of the first electric field 305 overlaps with a portion of the second electric field 310.

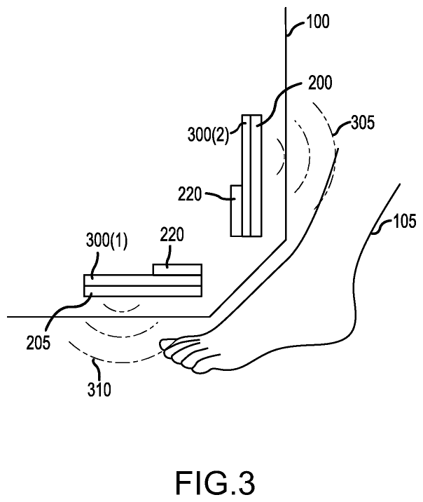

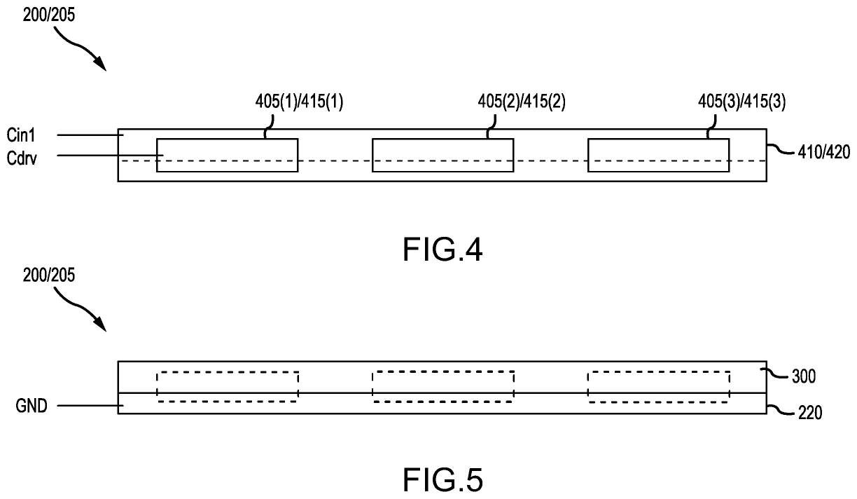

In various embodiments, and referring to FIG. 3-7, the first sensor pad 200 may comprise a first electrode 405 in communication with a second electrode 410. For example, the first and second electrodes 405, 410 may be configured to form a first capacitor and generate the first electric field 305. In an exemplary embodiment, one electrode, such as the first electrode 405, may be connected to a first drive signal Cdrv1 and operate as a transmission electrode (i.e., a drive electrode) and the remaining electrode, such as the second electrode 410, may operate as a reception electrode (i.e., an input electrode), or vice versa. The first and second electrodes 405, 410 may be formed on or within a non-conductive substrate 300, such as a printed circuit board, glass substrate, paper substrate, or a plastic substrate. In addition, the substrate 300 may be rigid (non-bendable) or flexible. Accordingly, the substrate 300 and sensor pads 200, 205 may be shaped or bent to accommodate a particular surface.

In various embodiments, each of the first and second electrodes 405, 410 may comprise a single, continuous conductive element, or a plurality of conductive elements having the same polarity (and referred to collectively as an electrode). For example, each electrode may be formed using any suitable metal and/or other conductive material.

In various embodiments, the second sensor pad 205 may comprise a third electrode 415 and a fourth electrode 420 in communication with each other. For example, the third and fourth electrodes 415, 420 may be configured to form a second capacitor and generate the second electric field 310. In an exemplary embodiment, one electrode, such as the third electrode 415, may be connected to a second drive signal Cdrv2 and operate as a transmission electrode (i.e., a drive electrode) and the remaining electrode, such as the fourth electrode 420, may operate as a reception electrode (i.e., an input electrode), or vice versa. The second sensor pad 205 and/or the third and fourth electrodes 415, 420 may be formed on or within a same substrate as the first sensor pad 205, or alternatively on or within a different substrate from the first sensor pad 205.

In various embodiments, each of the third and fourth electrodes 415, 420 may comprise a single, continuous conductive element, or a plurality of conductive elements having the same polarity (and referred to collectively as an electrode). For example, each electrode may be formed using any suitable metal and/or other conductive material.

According to various embodiments, a first portion of the first electric field 305 overlaps with a second portion of the second electric field 310, forming an overlapping region of electric fields.

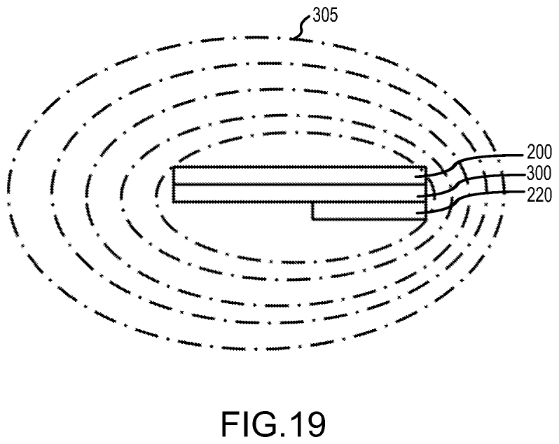

According to various embodiments, the capacitive sensor 230 may further comprise a separator electrode 220 (i.e., a fifth electrode) configured to shift or otherwise change the distribution of an electric field of a corresponding sensor pad. For example, and referring to FIG. 19, the first electric field 305 is skewed to the left resulting in electric field lines being closer together on the right side of the first sensor pad 200 than on the other side. In other words, the distribution of the electric field that is closest to the separator electrode 220 is different from the electric field that is farthest from the separator electrode 220. Accordingly, the portion of the electric field that is nearest to the separator electrode 220 has a lower intensity than the portion of the electric field that is farthest away from the separator electrode 220. A conventional sensor pad without the separator electrode 220 would exhibit a uniform electric field (and uniform intensity), wherein the electric field lines would be concentric and evenly spaced with each other.

In various embodiments, the separator electrode 220 may be positioned adjacent to the first and second sensor pads 200, 205 and within the overlapping region of the first and second electric fields 305, 310. The separator electrode 220 may comprise a single, continuous conductive element, or a plurality of conductive elements having the same polarity (and referred to collectively as an electrode). For example, the separator electrode 220 may be formed using any suitable metal and/or other conductive material.

In an exemplary embodiment, the separator electrode 220 may have a ground potential (i.e., zero volts). In alternative embodiments, the separator electrode 220 may have a potential greater than zero volts but less than the supply voltage V_{DD}. For example, the separator electrode 220 may have a potential of 0.1V, 3.3V, ½V_{DD}, or any other voltage potential suitable for changing distribution of the first and second electric fields 305, 310 in a desired manner.

According to a first embodiment, and referring to FIGS. 3, 4, and 5, the first sensor pad 205 may comprise a plurality of first electrodes, such as electrodes 405(1), 405(2) and 405(3), and the second electrode 410. In the present embodiment, the first and second electrodes are formed on a first surface of the first substrate 300 and the first electrodes 405(1), 405(2), 405(3) are nested within the second electrode 410. In addition, the separator electrode 220 is formed on a second surface of the first substrate 300, wherein the second surface is opposite the first surface.

In the present embodiment, the second sensor pad 210 may be similarly arranged. For example the second sensor pad 210 may comprise a plurality of third electrodes, such as electrodes 415(1), 415(2), and 415(3), and the fourth electrode 420. In the present embodiment, the third and fourth electrodes 415, 420 are formed on a first surface of a second substrate 300(2) and the third electrodes 415(1), 415(2), 415(3) are nested within the fourth electrode 420. In addition, the separator electrode 220 is formed on a second surface of the second substrate 300(2), wherein the second surface is opposite the first surface.

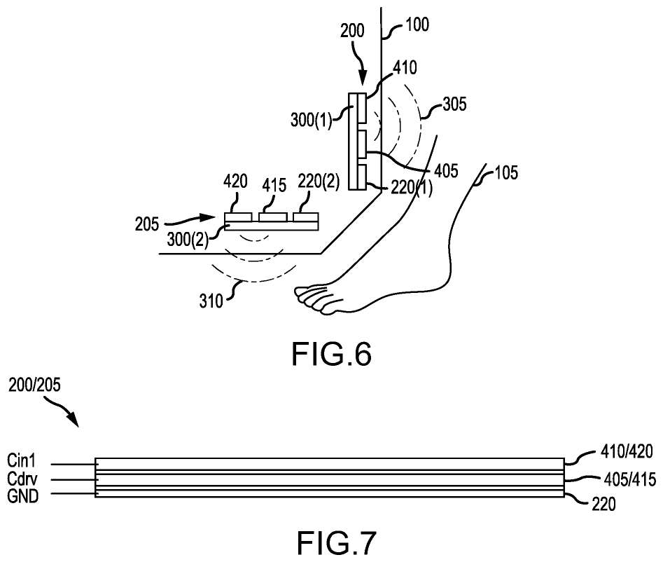

According to a second embodiment, and referring to FIGS. 6 and 7, the first sensor pad 200 may comprise the first electrode 405 and the second electrode 410, wherein the first and second electrodes 405, 410 are formed on a first surface of the first substrate 300. In the present embodiment, the first and second electrodes 405, 410 are arranged as horizontal stripes, parallel to each other. In addition, the separator electrode 220 is arranged as a horizontal stripe, parallel to the first and second electrodes 405, 410 and is formed on the first surface of the first substrate 300.

In the present embodiment, the second sensor pad 205 may be similarly arranged. For example the second sensor pad 205 may comprise the third electrode 415 and the fourth electrode 420, wherein the third and fourth electrodes 415, 420 are formed on a first surface of a second substrate 300(2). In the present embodiment, the third and fourth electrodes 415, 420 are arranged as horizontal stripes, parallel to each other. In addition, the separator electrode 220 is arranged as a horizontal stripe parallel to the third and fourth electrodes 415, 420 and is formed on the first surface of the second substrate 300(2).

In alternative embodiments, the first, second, third, and fourth electrodes 405, 410, 415, 420 may be arranged in any pattern suitable for generating a desired electric field. In addition, the separator electrode 220 may be arranged in any suitable position for changing the distribution of the electric field in a desired manner.

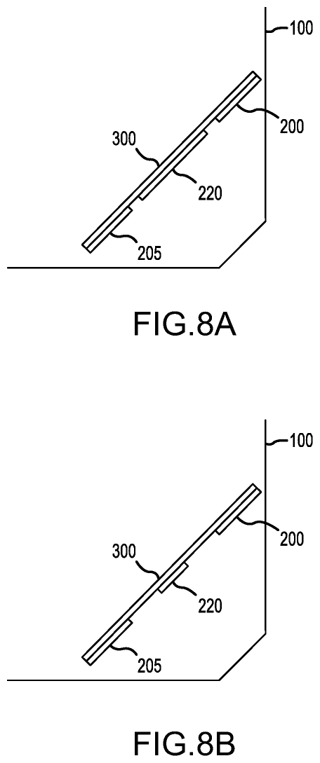

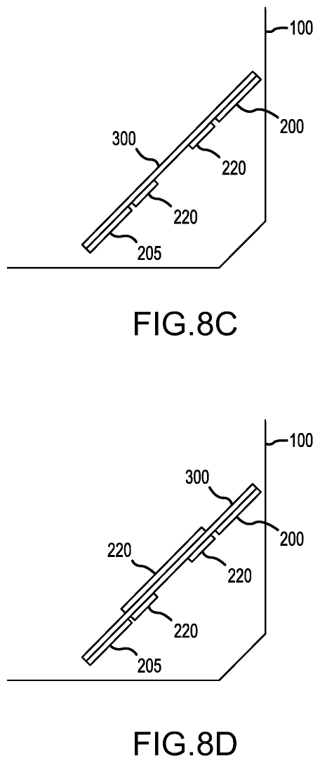

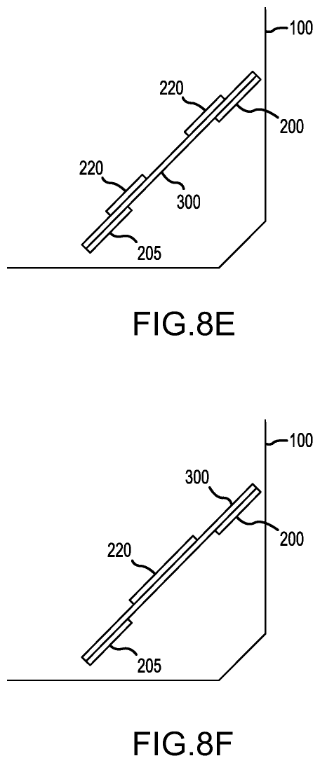

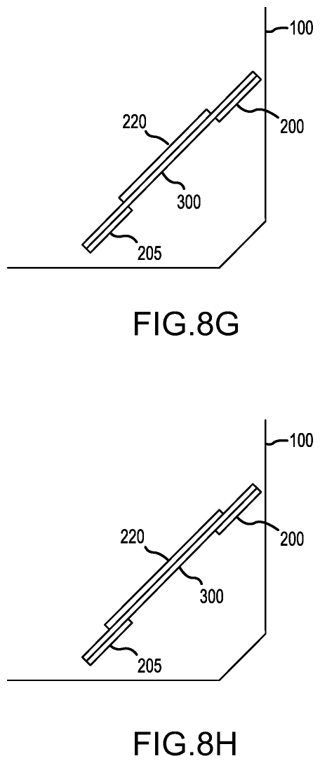

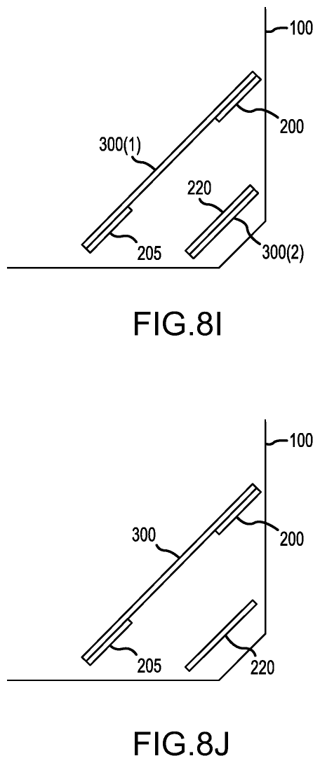

According to various embodiments, and referring to FIGS. 8A-8J, the first sensor pad 200, the second sensor pad 205, and the separator electrode 220 may be arranged in various positions with respect to each other.

For example, in various embodiments and referring to FIGS. 8A-8F, the separator electrode 220 may share a same substrate 300 as the first and second sensor pads 200, 205. Alternatively, and referring to FIG. 81, the separator electrode 220 may be formed on a separate substrate (e.g., 300(2)) from the first and second sensor pads 200, 205. Alternatively, and referring to FIG. 8J, the separator electrode 220 may be arranged separate from the first and second sensor pads 200, 205 and without a substrate.

In various embodiments, and referring to FIGS. 8A-8H, the separator electrode 200 may be positioned on a same side and/or an opposite side of the substrate 300 as the first and second sensor pads 200, 205. For example, and referring to FIGS. 8A-8C, the separator electrode 200 may be positioned on the same side of the substrate 300 as the first and second sensor pads 200, 205. Alternatively, and referring to FIGS. 8E-8H, the separator electrode 220 may be positioned on an opposite side of the substrate 300 from the first and second sensor pads 200, 205. Alternatively, and referring to FIG. 8D, the separator electrode 200 may comprise multiple elements and be positioned on both the same and opposite side of the substrate 300 as the first and second sensor pads 200, 205.

Referring to FIGS. 2 and 3, the capacitance sensing driver circuit 210 may be configured to measure and/or detect changes in the capacitance of the first and second sensor pads 200, 205 via changes in the first and second electric fields 305, 310. For example, the capacitance sensing driver circuit 210 may be coupled to the capacitive sensor 230 and configured to receive the first and second input signal Cin1, Cin2. The capacitance sensing driver circuit 210 may comprise any suitable circuit and/or system for sensing, detecting, or otherwise measuring changes in capacitance.

In addition, the capacitance sensing driver 210 may be configured to generate a drive signal, such as the first drive signal Cdrv1 and the second drive signal Cdrv2. For example, the capacitance sensing driver circuit 210 may be connected to the supply voltage V_{DD} and generate the drive signals Cdrv1, Cdrv2 according to the supply voltage V_{DD}.

The capacitance sensing driver circuit 210 may be configured to perform various processing functions, such as converting an input signal into a voltage value, amplification, signal conversion, and the like. For example, the capacitance sensing driver circuit 210 may comprise an amplifier (not shown), a signal converter (not shown), such as an ADC (analog-to-digital) and/or a DAC (digital-to-analog) for signal conversion, and the like. In various embodiments, the amplifier may be configured to convert each of the first input signal Cin1 (representing a first capacitance value) and the second input signal Cin1 (representing a second capacitance value) to a voltage and/or apply a gain the voltage. For example, the amplifier may comprise a differential amplifier for generating a voltage difference value. The amplifier may also be configured to amplify a signal by applying a gain to the voltage difference and generate an output voltage according to the voltage difference and/or the applied gain. The ADC may be connected to an output terminal of the amplifier and configured to convert the output voltage to a digital value. The capacitance sensing driver circuit 210 may transmit the capacitance information, such as in the form of a digital value, to the microcontroller 215.

The microcontroller 215 may be connected to the capacitance sensing driver circuit 210 and may transmit signals to and/or receive signals from the capacitance sensing driver circuit 210. For example, the microcontroller 215 may receive the capacitance data (e.g., a digital value) from the capacitance sensing driver circuit 210.

According to various embodiments, the microcontroller 215 may be configured to perform various control functions, logic functions, and the like. In addition, the microcontroller 215 may be configured to perform various computations, such as addition, subtraction, multiplication, and the like. The microcontroller 215 may comprise various logic gates and/or other circuitry to perform the desired computations, control functions, and/or logic functions.

The microcontroller 215 may receive the capacitance data (e.g., a digital value) from the capacitance sensing driver circuit 210, interpret the data, and perform an appropriate response and/or produce an appropriate output signal according to the capacitance data. For example, the microcontroller 215 may compare a first digital value (that reflects the first electric field 305) to a first predetermined threshold value, compare a second digital value (that reflects the second electric field 310) to a second predetermined threshold value, and determine whether an actionable event occurred based on the comparisons. An indication of an actionable event may occur if the first digital signal is above the first predetermined threshold and the second digital value is above the second predetermined threshold. In the case of a vehicle application, a kicking motion near the capacitive sensor 230 may produce particular digital values that indicate an actionable event (e.g., opening the trunk lid). The microcontroller 215 may generate an action signal if it determines that an actionable event occurred.

The microcontroller 215 may also operate in conjunction with a host device (e.g., the vehicle system). For example, the microcontroller 215 may transmit the action signal to the host device, wherein the host device performs a predetermined function based on the action signal, such as opening the trunk lid of the vehicle 100.

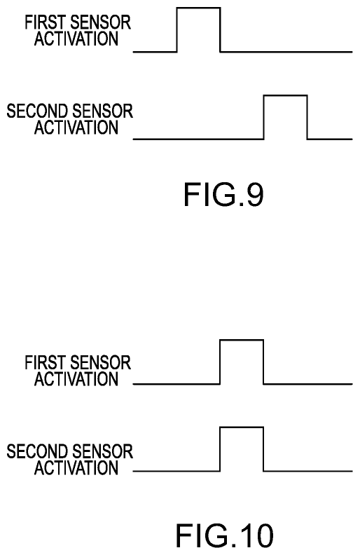

According to various embodiments, the first and second sensor pads 200, 205 may be used together to determine if an actionable event has occurred. For example, and referring to FIG. 9, the first and second sensor pads 200, 205 may be activated in sequence, such that only one sensor pad is activated (i.e., forming an electric field) at any given time. Alternatively, and referring to FIG. 10, the first and second sensor pads 200, 205 may be activated at the same time.

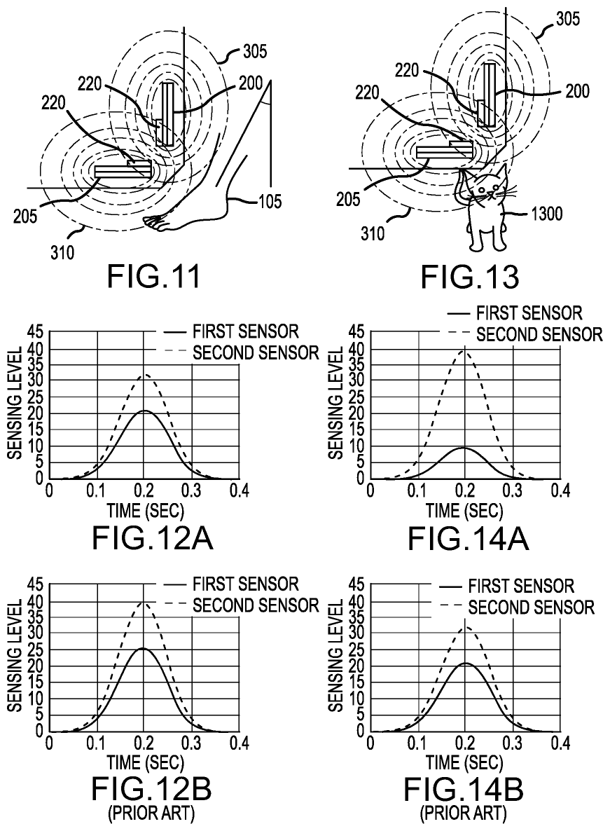

According to various embodiments, the sensor system 100 may distinguish between various conditions to determine if an actionable event has occurred. For example, and referring to FIGS. 11 and 13, a kicking motion near the capacitive sensor 230 may be an actionable event (FIG. 11), while an animal 1300 near the second sensor pad 205 may not be an actionable event (FIG. 13). According to the present conditions, and referring to FIGS. 12A and 14A, since the sensing levels of the first and second sensor pads 200, 205 in response to the condition of FIG. 11 greatly differ from the sensing levels of the first and second sensor pads 200, 205 in response to the condition of FIG. 13, the condition that corresponds to an actionable event is easily distinguishable. In contrast, and referring to FIGS. 12B and 14B, in a conventional sensor system, the sensing levels from each condition are nearly the same, and therefore not easily distinguishable.

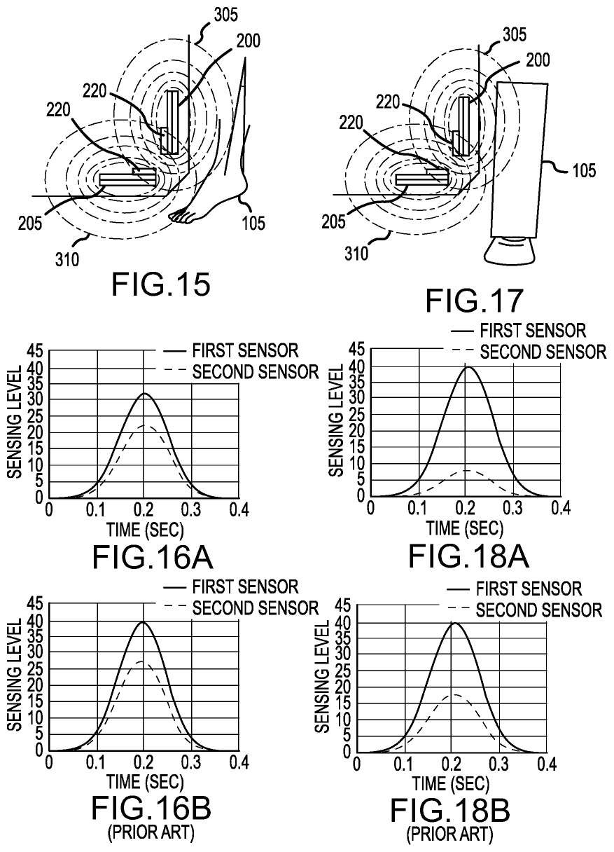

Similarly, and referring to FIGS. 15 and 17, a kicking motion near the capacitive sensor 230 may be an actionable event (FIG. 15), while a person 105 standing next to the first sensor pad 200 may not be an actionable event (FIG. 17). According to the present conditions, and referring to FIGS. 16A and 18A, since the sensing levels of the first and second sensor pads 205, 210 in response to the condition of FIG. 15 greatly differ from the sensing levels of the first and second sensor pads 205, 210 in response to the condition of FIG. 17, the condition that corresponds to an actionable event is easily distinguishable. In contrast, and referring to FIGS. 16B and 18B, in a convention sensor system, the sensing levels from each condition are nearly the same, and therefore not easily distinguishable.

The particular implementations shown and described are illustrative of the technology and its best mode and are not intended to otherwise limit the scope of the present technology in any way. Indeed, for the sake of brevity, conventional manufacturing, connection, preparation, and other functional aspects of the system may not be described in detail. Furthermore, the connecting lines shown in the various figures are intended to represent exemplary functional relationships and/or steps between the various elements. Many alternative or additional functional relationships or physical connections may be present in a practical system.

In the foregoing description, the technology has been described with reference to specific exemplary embodiments. Various modifications and changes may be made, however, without departing from the scope of the present technology as set forth. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any appropriate order and are not limited to the explicit order presented in the specific examples. Additionally, the components and/or elements recited in any system embodiment may be combined in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology.

1. A mutual capacitance proximity sensor, comprising:
a first sensor pad comprising a first electrode capable of forming a first electric field with a second electrode;
a second sensor pad positioned adjacent to the first sensor pad and comprising a third electrode capable of forming a second electric field with a fourth electrode; wherein a first portion of the first electric field overlaps with a second portion of the second electric field; and
a fifth electrode positioned adjacent to the first and second sensor pads, wherein the fifth electrode is configured to change a distribution of:
the first portion of the first electric field; and
the second portion of the second electric field.

2. The mutual capacitance proximity sensor according to claim 1, wherein the fifth electrode has a voltage potential that is between zero volts and one-half of a supply voltage.

3. The mutual capacitance proximity sensor according to claim 1, wherein the fifth electrode maintains a ground potential.

4. The mutual capacitance proximity sensor according to claim 1, wherein the first and second sensor pads are formed on a first surface of a single, continuous substrate.

5. The mutual capacitance proximity sensor according to claim 4, wherein the fifth electrode is formed on the first surface of the single, continuous substrate and positioned directly between the first and second sensor pads.

6. The mutual capacitance proximity sensor according to claim 4, wherein the fifth electrode is formed on a second surface of the substrate, wherein the second surface is opposite from and in parallel with the first surface.

7. The mutual capacitance proximity sensor according to claim 1, wherein the first and second sensor pads and the fifth electrode are each formed on separate and distinct substrates.

8. A method for detecting an object using a mutual capacitance proximity sensor, comprising:
forming a first electric field between a first electrode and a second electrode;
forming a second electric field between a third electrode and a fourth electrode;
forming an overlapping region of electric fields;
changing a distribution of the electric fields in the overlapping region;
measuring a change in the first electric field;
measuring a change in the second electric field; and
determining a presence of the object based on the measured change in at least one of the first and second electric fields.

9. The method according to claim 8, wherein the overlapping region of electric fields comprises a first portion of the first electric field that overlaps a second portion of the second electric field.

10. The method according to claim 8, wherein changing the electric fields in the overlapping region comprises providing a ground electrode in the overlapping region.

11. A proximity sensor system, comprising:
a capacitive sensor comprising:
a first sensor pad capable of generating a first electric field;
a second sensor pad positioned adjacent to the first sensor pad and capable of generating a second electric field;
a fifth electrode positioned adjacent to the first and second sensor pads, wherein the fifth electrode is configured to change a distribution of:
a first portion of the first electric field; and
a second portion of the second electric field;
a sensing circuit connected to the capacitive sensor and configured to measure a change in the first and second electric fields; and
a microcontroller connected to the sensing circuit and configured to generate a control signal according to the measured change in the first and second electric fields.

12. The proximity sensor system according to claim 11, wherein:
the first sensor pad comprises a first electrode in communication with a second electrode; and
the second sensor pad comprises a third electrode in communication with a fourth electrode.

13. The proximity sensor system according to claim 11, wherein the sensing circuit is configured to receive a supply voltage.

14. The proximity sensor system according to claim 11, wherein the fifth electrode has a voltage potential that is between zero volts and one-half of the supply voltage.

15. The proximity sensor system according to claim 11, wherein the fifth electrode maintains a ground potential.

16. The proximity sensor system according to claim 11, wherein the first and second sensor pads are formed on a first surface of a single, continuous substrate.

17. The proximity sensor according to claim 16, wherein the fifth electrode is formed on the first surface of the single, continuous substrate and is positioned directly between the first and second sensor pads.

18. The proximity sensor according to claim 16, wherein the fifth electrode is formed on a second surface of the substrate, wherein the second surface is opposite from and in parallel with the first surface.

19. The proximity sensor system according to claim 11, wherein the first and second sensor pads are formed on separate and distinct substrates.

20. The proximity sensor system according to claim 11, wherein the first portion of the first electric field overlaps with the second portion of the second electric field.
